(19) United States
(12) Patent Application Publication
(10) Pub. No.: US 2004/0023416 A1
(43) Pub. Date: Feb. 5, 2004

(54) Method for forming a paraelectric semiconductor device

(76) Inventors: Stephen R. Gilbert, San Francisco, CA (US); Sanjeev Aggarwal, Plano, TX (US); Scott Summerfelt, Garland, TX (US); Stevan G. Hunter SR., Fort Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/212,895

(22) Filed: Aug. 5, 2002

(51) Int. Cl. H01L 21/00; H01L 21/8242; H01L 21/31; H01L 21/469

(52) U.S. Cl. 438/3; 438/778; 438/785; 438/240

(57) ABSTRACT

A method is provided for forming a paraelectric semiconductor device by depositing a seed layer on an oxide electrode using a paraelectric material precursor and depositing a paraelectric layer on the seed layer using the paraelectric material precursor.

### BACKGROUND

1. Technical Field

The present invention relates generally to paraelectric materials and more particularly to ferroelectric materials for capacitors.

2. Background Art

As the electronic industry develops, several trends drive the development of new technologies. First, people want smaller and smaller products, which require less frequent replacement of batteries, such as cell phones, personal sound systems, digital cameras, etc. Second, in addition to being smaller and more portable, these products are required to have more computational power and more memory storage capability. Third, these devices are expected to maintain information, pictures, etc. even when the batteries die.

Non-volatile memories such as dynamic random access memories (DRAMs), electrically erasable programmable read only memories (EEPROMs), and flash EEPROMs are used in such products because they can maintain data without power. These memories include arrays of memory cells, in which each memory cell includes a memory cell capacitor and a memory cell access transistor.

Basically, the memory cell uses a capacitor to bold the electrical charge. The capability of holding a charge is called “capacitance” and the capacitance of a given capacitor is a function of the dielectric constant of the capacitor dielectric, the effective area of the capacitor electrode, and the thickness of the capacitor dielectric layer. Essentially, decreasing the thickness of the dielectric layer, increasing the effective area of the capacitor electrodes, and increasing the dielectric constant of the capacitor dielectric can increase the capacitance. For smaller products, it is desirable to have a small thickness and a high capacitance.

Decreasing the thickness of a capacitor dielectric layer below 100 Å generally reduces the reliability of the capacitor, because Fowler-Nordheim hot electron injection may create holes through the thin dielectric layers.

Increasing the effective area of the capacitor electrode generally results in a more complicated and expensive capacitor structure. For example, three dimensional capacitor structures such as stack-type structures and trench-type structures have been applied to 4 MB DRAMs, but these structures are difficult to apply to 16 MB or 64 MB DRAMs. A stack-type capacitor may have a relatively steep step due to the height of the stack-type capacitor over the memory cell transistor and trench-type capacitors may have leakage currents between the trenches when scaled down to the size required for a 64 MB DRAM.

Increasing the dielectric constant of the capacitor dielectric requires the use of relatively high dielectric constant materials. Currently, silicon dioxide (SiO₂) with a dielectric constant around ten is used. Higher dielectric constant materials, such as yttria (Y₂O₃), tantalum oxide (Ta₂O₅), and titanium oxide (TiO₂), have been tried.

Recently, paraelectric materials have been investigated which have even higher dielectric constants from a hundred to over a thousand. Paraelectric materials include ferroelectric materials such as Perovskite oxides. Examples of Perovskite oxides are PZT (PbZrₓTi₍₁₋ₓ₎O₃), BST (BaₓSr₍₁₋ₓ₎TiO₃), or STO (SrTiO₃), which have been used to provide a new family of memories called ferroelectric random access memories (FeRAMs). A ferroelectric material exhibits a spontaneous polarization phenomenon for excellent charge retention and improved non-volatility. When using a ferroelectric material as a dielectric layer for a capacitor, a thickness of hundredths of an angstrom can provide a dielectric equivalent of a 10 Å oxide layer.

Ferroelectric memories are not only non-volatile but they have the advantage that they are much easier to combine with logic circuits than existing memories such as Flash, static random access memory (SRAM), or DRAM. Thus, this technology combines the non-volatility of Flash with the cell size and ease of scaling of DRAM.

At this time, there are many different ferroelectric materials and a vast number of different formulations of ferroelectric materials that are being investigated. Many of the investigations lead to dead ends.

There have been major problems with developing the ferroelectric materials since a memory cell must maintain data without power, which means the material of the memory cell must be capable of holding an electrical charge, which represents one bit of data, for extremely long periods of time. The material must also be very thin to be compatible with the voltages used in current CMOS technology and it is critical that the ferroelectric material be of very high quality, possess a very smooth surface, and have no pin-hole defects. The crystallographic (111) orientation also needs to be maximized to obtain the best ferroelectric switching characteristics and the grain size must be controlled very precisely. Further, since standard logic circuitry associated with the ferroelectric memory has a maximum overall thermal budget, lower temperatures are desired for ferroelectric layer deposition to simplify integration of ferroelectric memory with standard logic circuitry. In addition, all of this needs to be done in a way that is manufacturable so that thousands and thousands of wafers can be consistently produced.

Solutions to these problem have been long sought, but have long eluded those skilled in the art.

### DISCLOSURE OF THE INVENTION

The present invention provides a method for forming a paraelectric semiconductor device by depositing a seed layer on an oxide electrode using a paraelectric material precursor and depositing a paraelectric layer on the seed layer using the paraelectric material precursor. This allows better grain size control, increased crystallographic (111) orientation control, smoother surfaces with under 3 nm rms surface roughness, no pin hole defects, and lower temperature processing under 600° C., which allows for maximum ferroelectric switching characteristics. Thus, wafers can be manufactured consistently and in large quantities. Further, lower deposition temperatures can be used to simplify integration of the paraelectric semiconductor device with standard logic circuitry.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a cross-sectional view of a two and a three dimensional ferroelectric memory integrated circuit in accordance with the present invention;

FIG. 2 is a closeup view of a memory capacitor in accordance with the present invention;

FIG. 3 is a view of a two-chamber processing system used to manufacture the composite seed layer in accordance with the present invention;

FIG. 4 is a view of a single chamber processing system used to manufacture the composite seed layer in accordance with the present invention; and

FIG. 5 is a simplified flow chart of the method of manufacturing a ferroelectric capacitor in accordance with the present invention.

### BEST MODE FOR CARRYING OUT THE INVENTION

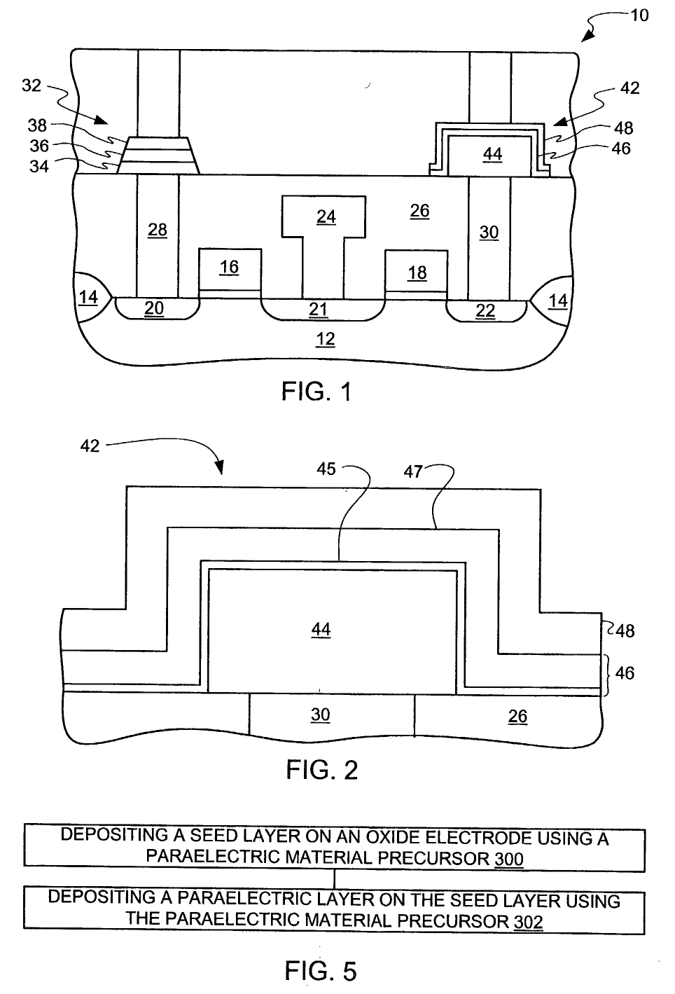

Referring now to FIG. 1, therein is shown a cross-sectional view of a three-dimensional ferroelectric memory integrated circuit 10 using a ferroelectric layer formed using materials of the present invention. A semiconductor substrate 12 has a shallow trench isolation oxide layer 14, gates and gate dielectrics 16 and 18, and source/drain regions 20-22. A bit line 24 is formed in an interlayer dielectric (ILD) layer 26 in contact with one source/drain region 21, and buried contacts 28 and 30 are formed through the ILD layer 26 and are respectively in contact with source/drain regions 20 and 22.

In a two dimensional memory capacitor 32, an oxide or lower electrode 34 is deposited on the ILD layer 26 in contact with the buried contact 28. A composite ferroelectric layer 36 is deposited over the lower electrode 34. And, an upper electrode 38 is deposited over the composite ferroelectric layer 36. Basically, the gates and gate dielectrics 16 and 18, and the source/drain regions 20-22 form the transistors of the ferroelectric memory integrated circuit 10 while the lower electrode 34, the composite ferroelectric layer 36, and the upper electrode 38 form the two dimensional memory capacitor 32. The two dimensional memory capacitor 32 is relatively easy to manufacture because successive layers of material are deposited on a flat surface and the sides are etched to form the capacitor structure.

In a three dimensional memory capacitor 42, a lower electrode 44 is deposited on the ILD layer 26 in contact with the buried contact 30. The lower electrode 44 in this case is a three dimensional structure with vertical sides. A composite ferroelectric layer 46 is deposited conformally over the lower electrode 44 including its sides. And, an upper electrode 48 is deposited conformally over the composite ferroelectric layer 46 including its sides. Again, the gates and gate dielectrics 16 and 18, and the source/drain regions 20-22 form the transistors of the ferroelectric memory integrated circuit 10 while the lower electrode 44, the composite ferroelectric layer 46, and the upper electrode 48 form the three dimensional memory capacitor 42. The three dimensional memory capacitor 42 is relatively difficult to manufacture because successive layers of material are deposited on horizontal and vertical surfaces before etching.

The lower electrodes 34 and 44 and the upper electrode 38 and 48 are formed from a noble metal material or compound such as platinum (Pt), iridium (Ir), or ruthenium (Ru), but preferably IrO₂, or RuO₂. The composite ferroelectric layers 36 and 46 are reactive seed layers of oxides of metals such as titanium (Ti), zirconium (Zr), or lead (Pb) forming TiOₓ, ZrOₓ, (Ti,Zr)Oₓ, PbO, PbTiO₃, Pb(Zr,Ti)O₃, etc. under ferromagnetic Perovskite oxides of metals such as titanium, zirconium, lead, barium (Ba), strontium (Sr), or bismuth (Bi) forming PZT (PbZrₓTi₍₁₋ₓ₎O₃), BST (BaₓSr₍₁₋ₓ₎TiO₃), STO (SrTiO₃), BTO (Bi₄Ti₃O₁₂), or SBT (SrBiz₂Ta₂O₉).

In the past, there have been major problems in the deposition of the seed layers and the ferroelectric layers. The seed layers can cause problems because they are deposited at a relatively high temperature and significantly reduce the thermal budget. The ferroelectric layers cause additional problems because of the need to control the microstructure and surface roughness of the ferroelectric layer. Control of the microstructure permits decreasing the ferroelectric layer thickness such that each generation of technology allows the operating voltage of the ferroelectric capacitor to scale directly downward. Basically, it is desirable to operate with less voltage to save power and thus it is desirable to have as thin a ferroelectric layer as possible. Currently, developments have substantially stopped at film thicknesses of between 50-70 nm because it has not been possible to sufficiently control the microstructure and surface roughness of the ferroelectric layer.

During investigations by the inventors, it has been unexpectedly discovered that when the ferroelectric layer is deposited on a lower electrode, the ferroelectric deposition process can uncontrollably modify the top surface of the lower electrode material. For example, for a lower electrode of iridium oxide, a single-step metal organic chemical vapor deposition process using metal organic precursors will reduce the iridium oxide, i.e., remove oxygen, to leave a pitted iridium lower electrode. This disturbs the microstructure of the ferroelectric layer deposited on it as well as impacting its surface roughness and the adhesion of subsequently deposited materials such as the upper electrode.

For example, metal organic chemical vapor deposition has been used for depositing ferroelectric layers at a relatively high wafer temperature of 600-610° C. at a pressure of 4 Torr. To minimize fatigue (polarization loss caused by repeated capacitor switching), the ferroelectric layer has been preferably deposited on an iridium oxide or iridium oxide/iridium lower electrode. Oxide electrodes such as iridium oxide are known to significantly improve fatigue performance compared to the use of noble metals such as platinum and iridium alone.

It has been determined that the highly reducing ambient created by the solvent and precursors used in the ferroelectric deposition process results in the surface of the lower electrode not being stable and changing as the ferroelectric layer is deposited. Moreover, loss of oxygen from the iridium oxide electrode degrades the capacitor fatigue characteristics. The ferroelectric surface roughness scales linearly with the thickness of the ferroelectric layer and this has limited the minimum thickness to over 50 nm. Below 50 nm, the ferroelectric layer exhibits high leakage and electrodes are often shorted through pinhole defects in the ferroelectric layer.

It has also been determined that it is desirable to maximize the (111) crystallographic orientation of the ferroelectric layer since this provides the best ferroelectric switching characteristics. Precise control of grain size is also required because it affects the distribution of properties across the memory array.

It has also been discovered that ferroelectric PZT layers containing lead (Pb) are self-correcting when the layers are deposited at high wafer temperatures of 600-610° C. The self-correcting phenomenon describes a processing region in which the Pb composition in the layer is insensitive to changes in the Pb/(Zr+Ti) ratio in the gas phase. This phenomenon occurs in the CVD PZT process, which provides for a more robust deposition process. These high temperatures are desirable because they provide a large self-correcting region.

However, these high temperatures cause the ferroelectric layer deposition process to have the largest thermal budget of all the process steps used to fabricate the ferroelectric memory integrated circuit (i.e., the cumulative time at temperature is one of the highest for all of the semiconductor manufacturing processes). Since the standard logic circuitry associated with the ferroelectric memory has a maximum overall thermal budget, the lower the temperatures used for ferroelectric layer deposition, the simpler the integration of ferroelectric memory with standard logic circuitry.

Unfortunately, it has also been determined that the self-correcting behavior is diminished below a wafer temperature of 590° C. when standard process conditions are used. Below 550° C., the self-correcting behavior is no longer observed.

Referring now to FIG. 2, therein is shown a close-up of the three dimensional memory capacitor 42 in accordance with the present invention. The three dimensional memory capacitor 42 is made by a two-step process, which first deposits a reactive seed layer 45 and then a ferroelectric material 47.

In the present invention, it has been discovered that the deposition of the reactive seed layer 45 during the initial stages of the ferroelectric layer deposition will eliminate the degradation of the oxide electrode and avoid the formation of a non-hysteretic interfacial layer. The seed metals may be deposited by chemical vapor deposition or physical vapor deposition in an oxygen atmosphere to a thickness of less than 5 nm to form the seed metal oxide. Due to the thinness of this metal oxide layer, the final thickness of the ferroelectric layer plus the reactive seed layer can start off at approximately the same thickness as that obtained using a single step process but the final thickness can be significantly reduced below 50 nm.

It will be understood that the above discovery is also applicable to two dimensional memory capacitors and provides both with the advantages of better grain size control, increased crystallographic (111) orientation control, smoother surfaces with under 3 nm rms surface roughness, no pin hole defects, and lower temperature processing under 600° C.

It was also discovered that reduction of the oxide electrode can be inhibited by flowing an oxidizer, such as oxygen or preferably nitrous oxide, either during the deposition process or after the initial nucleation of the ferroelectric material to form the TiOₓ, ZrOₓ, (Ti,Zr)Oₓ, PbO, PbTiO₃, Pb(Zr,Ti)O₃, etc. The reactive seed layer oxide needs to be compatible with the ferroelectric materials and their precursors chemicals.

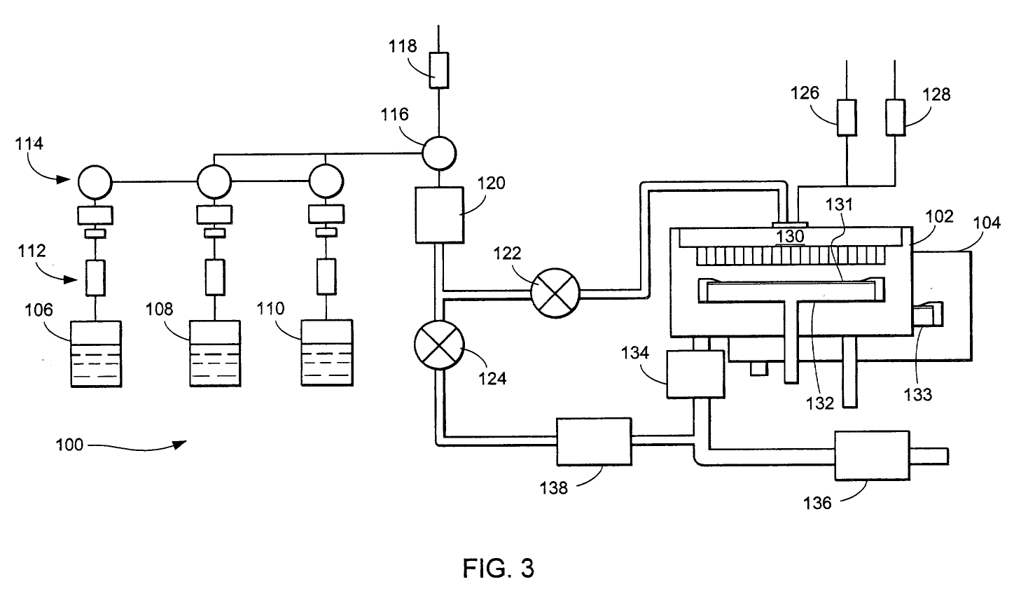

Referring now to FIG. 3, therein is shown a two-chamber processing system 100 to manufacture the composite ferroelectric layer 36 or 46 in accordance with the present invention. The two-chamber processing system 100 can be a physical vapor deposition system or a spin-on deposition system, but a chemical vapor deposition (CVD) system is preferred.

The two-chamber processing system 100 has first and second CVD deposition chambers 102 and 104. The first CVD deposition chamber 102 is shown connected for deposition of a reactive seed layer in accordance with the present invention.

The first CVD deposition chamber 102 is fed from a solvent supply 106, a first precursor ampoule 108 and a second precursor ampoule 110. Flow control valves 112 connect the solvent supply 106, the first precursor ampoule 108 and the second precursor ampoule 110 to a main mixing valve 116.

The main mixing valve 116 mixes the solvent and precursors with a carrier gas from a carrier gas inlet 118 and feeds the mixture to a vaporizer 120. The vaporizer 120 is connected to a diverter valve 122 and a bypass valve 124.

The diverter valve 122 is connected to the first CVD deposition chamber 102 adjacent to inlets connected to an oxygen inlet 126 and an oxidizer gas inlet 128, which is connected to a CVD system 130. The CVD gasses flow downward over a wafer 131, which rests on a wafer heater 132. Gasses are returned through a pressure control 134 into a chemical recovery cold trap 136. The bypass valve 124 is also connected to a chemical recovery cold trap 138 which feeds into the chemical recovery cold trap 136.

In operation, the two-chamber processing system 100 deposits the reactive seed layer 45 of FIG. 2 first. The solvent and the seed layer precursor are mixed together. The precursor and solvents are selected to not degrade the oxide electrode in the same way that the ferroelectric precursors do. By way of example, the solvent can be Octane:Decane:Adduct, a first precursor of Zr(O-iPr)₂(thd)₂: Ti(O-iPR)₂(thd)₂ at a 60:40 ratio, and a second precursor Zr(O-iPr)₂(thd)₂: Ti(O-iPR)₂(thd)₂ at a 20:80 ratio where: Zr(OiPr)₂(thd)₂ is bis(isopropoxy)bis(tetramethylheptanedianoto)Zr; Ti(O-iPr)₂(thd)₂ is bis(isopropoxy)bis(tetramethylheptanedianoto)Ti; and Pb(thd)₂(pmdeta) is bis(tetramethylheptanediaonto)Pb-pentamethyldiethylenetriamine adduct.

The carrier gas from the carrier gas inlet 118 can be an inert gas, such as nitrogen, argon, or helium. The mixture is vaporized in the vaporizer 120 at a temperature of approximately 190° C. and the mixture is passed through the diverter valve 122 into the CVD system 130. Oxidizers, generally O₂ and N₂O, are supplied respectively through the oxygen inlet 126 and the N₂0 gas inlet 128. The ratio of oxygen to N₂0 can run from 0 to 100% N₂0.

After the reactive seed layer is deposited, the second CVD deposition chamber 104 replaces the first CVD deposition chamber 102.

During the chemical vapor deposition process, it was unexpectedly discovered that the pressure used to deposit the seed layer could also be used for the ferroelectric material deposition. This pressure is between 1 and 10 Torr, and preferably between 2 and 4 Torr, which is also a critical pressure for extending the self-correcting region of the reactive seed layer deposition.

During the chemical vapor deposition process, it was also unexpectedly discovered that the temperature used to deposit the reactive seed layer could also be used for the ferroelectric material deposition. This temperature is 590° C. This has been found to be a critical temperature for extending the self-correcting region while significantly reducing the thermal budget for the deposition of combined ferroelectric layer. With different combinations of pressures and chemicals, temperatures below 590° C. have been found to be workable. It is speculated that the seed layer creates nucleation sites that permit the ferroelectric material to form more readily so it can nucleate itself and grow at a lower temperature.

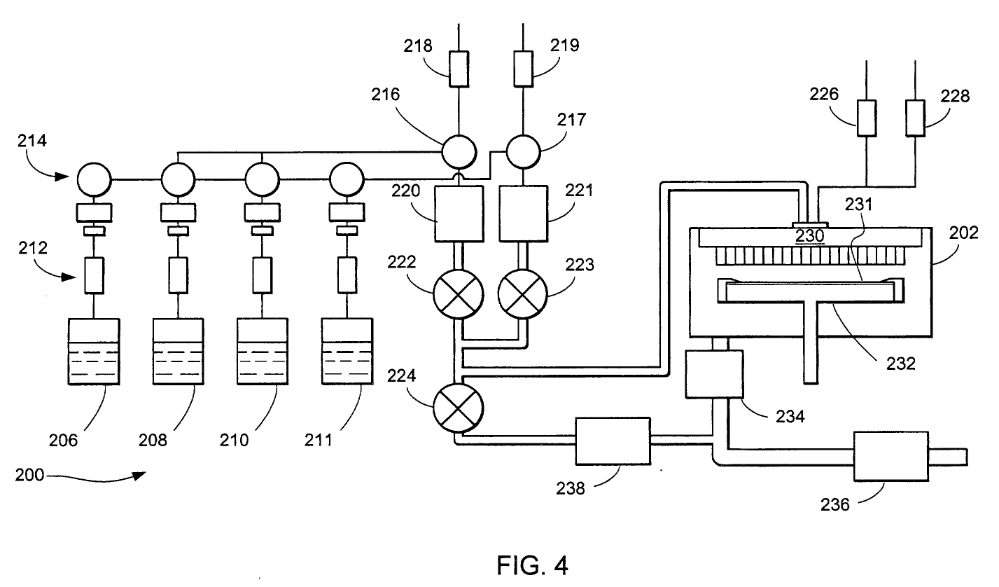

Referring now to FIG. 4, therein is shown a processing system 200 to manufacture the composite ferroelectric layer 36 or 46 of FIG. 1 in accordance with the present invention. Again, the processing system 200 can be a physical vapor deposition system or a spin-on deposition system, but a chemical vapor deposition system is preferred.

The processing system 200 has a single CVD deposition chamber 202. The CVD deposition chamber 202 is shown connected for deposition of a seed layer in accordance with the present invention.

The CVD deposition chamber 202 is fed from a solvent supply 206, a first precursor ampoule 208, a second precursor ampoule 210, and a third precursor ampoule 211. Flow control valves 212 connect the solvent supply 206, the first precursor ampoule 208, the second precursor ampoule 210, and the third precursor ampoule to first and second main mixing valves 216 and 217.

The first and second main mixing valves 216 and 217 mix the solvent and precursors with a carrier gas from a carrier gas inlet 218 and feed the mixture to first and second vaporizers 220 and 221.

The first and second vaporizers 220 and 221 are connected to first and second diverter valves 222 and 223 and a bypass valve 224.

The first and second diverter valves 222 and 223 are connected to a CVD deposition chamber 202 adjacent to inlets connected to an oxygen inlet 226 and an oxidizer gas inlet 228 which is connected to a CVD system 230. The CVD gasses flow downward over a wafer 231, which rests on a wafer heater 232. Gasses are returned through a pressure control 234 into a chemical recovery cold trap 236. The bypass valve 224 is also connected to a chemical recovery cold trap 238 which feeds into the chemical recovery cold trap 236.

In operation, the processing system 200 deposits the reactive seed layer 45 of FIG. 2 first. The solvent and the precursors are mixed together. The precursors and solvents are selected to not degrade the oxide electrode in the same way that the ferroelectric precursors do. By way of example, the solvent can be an Octane:Decane:Adduct mixture of a first precursor of Zr(O-iPr)₂(thd)₂: Ti(O-iPR)₂(thd)₂ at a 60:40 ratio, a second precursor of Zr(OiPr)₂(thd)₂: Ti(O-iPr)₂(thd)₂ at a 20:80 ratio, and a third precursor.

The carrier gas from the carrier gas inlet 218 can be an inert gas, such as nitrogen, argon, or helium. The mixture is vaporized in the first and second vaporizers 220 and 221 at a temperature of approximately 190° C. and is passed through the first and second diverter valves 222 and 223 into the CVD system 230. Oxidizers, generally O₂ and N₂O, are supplied respectively through the oxygen inlet 226 and the N₂O gas inlet 228. The ratio of oxygen to oxidizer can run from 0 to 100% oxidizer. The oxidizers can be applied either during the deposition process or after initial nucleation of the reactive seed layer.

The above system has the reactive seed layer deposition and the ferroelectric layer deposition in the same CVD deposition chamber 202 with purging in between. The first and second vaporizers 220 and 221 are required because the reactive seed layer and the ferroelectric layer have dissimilar vaporization characteristics. For example, for a (TiZr)O₂ seed layer, the precursor would be Zr(O-ipr)₂(thd)₂:Ti(O-iPr)₂(thd)₂ at 30:70 ratio from the precursor ampoule 211 through the second vaporizer 221. For a PZT fetroelectric layer, the precursors would be Pb(thd)₂ pmdeta:Zr(O-iPr)₂(thd)₂:Ti(O-iPr)₂(thd)₂ at 0.286:0.286:0.429 ratio and Pb(thd)₂ pmdeta:Zr(O-iPr)₂(thd)₂:Ti(O-iPr)₂(thd)₂ at 0.649:0.142:0.209 ratio respectively from the precursor ampoules 208 and 210 through the first vaporizer 220. The same pressure and temperature conditions as described above have also worked for this embodiment.

In an alternate embodiment, the oxidizer in the oxide electrode is used to create an ultra-thin and uniform oxide seed layer upon deposition of a pure metal. For example, only Ti is deposited. The advantage of this technique is simplified chemistry and hardware plus enhanced nucleation of the ferroelectric layer due to the formation of PbTiO₃ seed layer that might also become doped by diffusion from the ferroelectric layer deposited above it. The Ti precursor requires no extra solvent and the primary advantage is that the amount of reducing chemicals, such as carbon or hydrogen, are minimized. The Ti precursor is a liquid near room temperature and is vaporized using the standard vaporizer.

The CVD process is performed by heating the wafer to between 400-600° C. and flowing the precursor over the wafer with a carrier gas. The oxidizers could be flowed either during the deposition process or after the initial nucleation stage. The precursor easily oxidizes using the oxygen from the oxidized electrode.

One advantage of this type of reaction is that without additional oxygen, the reaction will stop when all of the oxidized electrode has been covered by TiOₓ. Therefore, a uniform layer of TiOₓ will be formed with minimum reduction of the oxide of the lower electrode. After deposition of the TiOₓ seed layer, the wafer can be exposed to oxygen either in this process or as part of the subsequent ferroelectric layer deposition. It is possible to perform the seed layer deposition as part of the ferroelectric deposition with hardware additions or it can be performed in a separate chamber.

The two-step approach of the present invention results in avoiding the reduction of the oxidized lower electrode during deposition of the ferroelectric film, which decreases the ferroelectrie surface roughness for improved ferroelectric film thickness scaling. Also the seed layer could be deposited to a smaller grain size which leads to better grain size control and texture of the ferroelectric layer microstructure. Finally, the reduced temperature depositions provide a reduced thermal budget for the combined ferroelectric layer.

Referring now to FIG. 5, therein is shown a flow chart according to the present invention including a process 300 of depositing a seed layer on an oxide electrode using a paraelectric material precursor and a process 302 of depositing a paraelectric layer on the seed layer using the paraelectric material precursor.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations which fall within the spirit and scope of the included claims. All matters hither-to-fore set forth herein or shown in the accompanying drawings are to be interpreted in an illustrative and non-limiting sense.

The invention claimed is:

1. A method for forming a paraelectric semiconductor device:
depositing a seed layer on an oxide electrode using a paraelectric material precursor; and
depositing a paraelectric layer on the seed layer using the paraelectric material precursor.

2. The method as claimed in claim 1 wherein depositing the paraelectric layer includes using nitrous oxide (N₂O) in the deposition process.

3. The method as claimed in claim 1 wherein depositing the paraelectric layer includes using a pressure between 1 and 10 Torr.

4. The method as claimed in claim 1 wherein depositing the seed layer includes depositing the seed layer at a pressure between 1 and 10 Torr.

5. The method as claimed in claim 1 wherein depositing the seed layer includes depositing the seed layer on the oxide electrode at a temperature under 600° C.

6. The method as claimed in claim 1 wherein depositing the seed layer includes using an oxidizer gas to provide an oxidized seed layer.

7. The method as claimed in claim 1 wherein depositing the seed layer includes depositing the seed layer with seed grains having a (111) crystallographic orientation.

8. The method as claimed in claim 1 wherein depositing the seed layer includes depositing the seed layer with a surface roughness under 3 nm rms.

9. The method as claimed in claim 1 wherein depositing the seed layer and the paraelectric layer includes depositing the seed layer and the paraelectric layer to a thickness under 50 nm.

10. The method as claimed in claim 1 wherein depositing the seed layer includes depositing the seed layer by a process selected from a group consisting of chemical vapor deposition, physical vapor deposition, spin-on deposition, and a combination thereof.

11. A method for forming a ferroelectric semiconductor device:
providing an oxide electrode;
depositing a seed layer on the oxide electrode using a ferroelectric material precursor without reducing the oxide of the oxide electrode; and
depositing a ferroelectric layer on the seed layer using the ferroelectric material precursor.

12. The method as claimed in claim 11 wherein depositing the paraelectric material is performed between 2 and 4 Torr using nitrous oxide (N₂O) in the deposition process.

13. The method as claimed in claim 11 including:
depositing the ferroelectric layer at a pressure between 2 and 4 Torr; and
depositing a further electrode over the ferroelectric layer.

14. The method as claimed in claim 11 wherein depositing the seed layer includes depositing the seed layer at a pressure between 2 and 4 Torr.

15. The method as claimed in claim 11 wherein depositing the seed layer includes depositing the seed layer on the oxide electrode at a temperature under 600° C.

16. The method as claimed in claim 11 wherein depositing the seed layer includes using an oxidizer gas with nitrous oxide (N₂O) to provide an oxidized seed layer.

17. The method as claimed in claim 11 wherein depositing the seed layer includes:
depositing the seed layer with seed grains having a (111) crystallographic orientation; and
depositing the ferroelectric layer with ferroelectric grains having a (111) crystallographic orientation.

18. The method as claimed in claim 11 wherein depositing the seed layer includes depositing the seed layer with a surface roughness under 3 nm rms with the ferroelectric layer having a surface roughness under 3 nm rms.

19. The method as claimed in claim 11 wherein:
depositing the seed layer includes depositing the seed layer to a thickness under 5 nm; and
depositing the seed layer and the ferroelectric layer includes depositing the seed layer and the ferroelectric layer to a thickness under 50 nm.

20. The method as claimed in claim 11 wherein:
depositing the seed layer includes depositing the seed layer by a process selected from a group consisting of chemical vapor deposition, physical vapor deposition, spin-on deposition and a combination thereof;
depositing the ferroelectric layer includes depositing the ferroelectric layer by a process selected from a group .consisting of chemical vapor deposition, physical vapor deposition, spin-on deposition and a combination thereof; and
depositing the seed layer and the ferroelectric layer uses a process selected from a group consisting of single and multiple chamber depositions.
